(19) United States
(12) Patent Application Publication
(10) Pub. No.: US 2013/0056258 A1
(43) Pub. Date: Mar. 7, 2013

(54) ELECTROMAGNETIC SHIELDING ADHESIVE TAPE

(71) Applicants: Wen Jie Zhang, Shanghai (CN); Rong Wu, Shanghai (CN)

(72) Inventors: Wen Jie Zhang, Shanghai (CN); Rong Wu, Shanghai (CN)

(73) Assignee: 3M INNOVATIVE PROPERTIES COMPANY, ST. PAUL, MN (US)

(21) Appl. No.: 13/697,873

(22) PCT Filed: May 10, 2011
(86) PCT No.: PCT/US11/35817

§ 371 Date: Nov. 14, 2012

(30) Foreign Application Priority Data
May 14, 2010 (CN) 201010176310.0

(51) Int. Cl. H05K 9/00

(52) U.S. Cl. 174/388; 174/350

(57) ABSTRACT

The invention provides an electromagnetic shielding adhesive tape, comprising: a resin film layer; and an electromagnetic interference shielding layer with a sandwiched structure, which is laminated with the resin film layer and comprises: a first adhesive layer bonded to one side of the resin film layer; a second adhesive layer; and a conductive metal layer provided between the first adhesive layer and the second adhesive layer.

### FIELD OF THE INVENTION

The present invention relates to a novel electromagnetic shielding adhesive tape which is mainly used to provide electromagnetic shielding and insulating protection for the key parts in electronic products, and specifically, consumable electronic products.

### BACKGROUND

Electromagnetic shielding adhesive tapes are widely used to provide electromagnetic shielding and protection for the key parts in electronic products, and specifically, consumptive electronic products. At present, the main electromagnetic shielding adhesive tapes are composed of a metal foil 1 and a (conductive or non-conductive) pressure sensitive adhesive layer 2 (as shown in FIG. 1(a)), and a resin thin film 3 (as shown in FIG. 1(b)) can further be provided on the metal foil 1. Wherein, the metal used as a backing is mainly copper or aluminum. This kind of adhesive tapes is wildly used in the industry all through because it has the features of mature products, good shielding effect and convenient application.

However, the metal foil type adhesive tapes have some intrinsic disadvantages of: (1) the metal (specifically, copper) is oxidized easily and thus the conductive performance and electromagnetic shielding effect of the whole product are affected; (2) the whole adhesive tape is poorer in softness and compliance performances, tends to produce folds during application, and tends to be torn in the width direction because of the presence of a metal foil; (3) the metal foil itself has such a larger thickness that the corresponding adhesive tape has a thicker thickness, which is hard to satisfy the designing demand of “lightness, thin and durability” for the present consumable electronic products; (4) these electromagnetic shielding type adhesive tapes generally have to be die-cut into specific shapes upon application, and additionally, the traditional metal foil type adhesive tapes are prone to produce edge curling (that is, crimping) or fins upon die-cutting, which causes inconvenience or inutility for the product application; and (5) the surface of the metal material is prone to produce scorings and breakages, which affect the product application greatly.

In order to overcome the intrinsic disadvantages of the metal foil type adhesive tapes, at present, some products are provided with a layer of resin thin film with the functionalities of surface insulation and protection on a surface of metal thereof. The common material is polyethylene terephthalate (PET). However, this kind of adhesive tape is still in need of improvements in softness, compliance, tearing resistance, and die-cutting performance or the like.

In view of the above problems, at present some inventions have provided the corresponding technical solutions. The main method thereof is to utilize a resin thin film 3 plated with a conductive metal layer 4 on one side or both sides provided on a pressure sensitive adhesive layer 2 (together with the conductive metal layer 4) for replacing the metal foil 1 or the metal foil 1 coated with a resin thin film 3 in FIG. 1(a), 1(b). The typical structures thereof are shown in FIGS. 2(a), (b).

For example, Chinese Patent CN 1234423A and U.S. Pat. No. 6,235,385 provide a novel electromagnetic shielding adhesive tape structure. The conductive adhesive tape is an adhesive tape with an extreme thin thickness which is prepared by forming a conductive agglutinant on a metal evaporation plating layer of a resin thin film. The metal evaporation plating layer is formed by evaporation plating a conductive metal substance on one side of the resin thin film via the vacuum evaporation plating method or evaporation plating a mesh-shaped metal evaporation plating layer on one side of the resin thin film. The method provided in the invention can preferably overcome the disadvantages of the present conductivity shielding adhesive tapes. However, the metal layer formed by evaporation plating is in need of improvements in the binding force thereof with the resin thin film and the scraping resistant performance thereof. Otherwise, it will not only affect the appearance of products, but also affect the use effect thereof.

U.S. Pat. No. 4,686,127 further discloses a conductive adhesive tape with a novel structure. It comprises a polypropylene thin film coated with a polyurethane film on at least one surface thereof, wherein a surface of the polyurethane film is sputtering plated with a layer of ductile metal, such as gold, while a surface of the metal is coated with an adhesive film with a release paper. However, the patent utilizes an expensive metal, resulting in an exorbitant cost. Additionally, the metal layer formed by sputtering plating has an insufficient binding force with the resin thin film, and thus the use effect thereof is affected.

Japanese Patent JP 2005277145 suggests a structure of a new conductivity shielding adhesive tape using a resin thin film plated with a metal on a surface thereof, wherein a conductive adhesive film is attached to one side or both sides of the resin thin film and the conductive particles are nickel powder. The disadvantage of the patent is that the metal layer formed by sputtering plating has an insufficient binding force with the resin thin film, and thus the use effect thereof is affected.

Japanese Patent JP 2005150626 suggests a novel electromagnetic shielding elastic material. The structure and preparation process thereof are specified as follows: forming a conductive metal layer on a surface of a re-stickable adhesive film by a process of vacuum sputtering plating or electroplating, and then attaching the conductive metal layer to another elastic material together.

However, as present, it is still needed to develop an electromagnetic shielding adhesive tape which still has superior adhesion and electromagnetic shielding efficiency even under a condition of high temperature and high humidity.

### SUMMARY

In order to solve the above problems, the inventor has performed extensive research. The inventor unexpectedly found that, by using a special “sandwich” structure (that is, “adhesive layer-conductive metal layer-adhesive layer”), an electromagnetic shielding adhesive tape can be made to have a superior peeling force and a superior electromagnetic shielding efficiency simultaneously, and further maintain the superior performances even under a condition of high temperature and high humidity.

Therefore, the invention provides an electromagnetic shielding adhesive tape, comprising:
a resin film layer; and
an electro-magnetic interference shielding layer with a sandwiched structure, which is laminated with the resin film layer and comprises:
   a first adhesive layer bonded to one side of the resin film layer;
   a second adhesive layer; and
   a conductive metal layer provided between the first adhesive layer and the second adhesive layer.

The electromagnetic shielding adhesive tape of the invention with the above specific structure has a superior peeling force and a superior electromagnetic shielding efficiency simultaneously and further maintains the superior performances even under a condition of high temperature and high humidity. It can be widely used to provide electromagnetic shielding and protection for the key parts in electronic products, and specifically, consumptive electronic products, and especially, electronic products used in a rigorous environment under high temperature and high humidity.

### BRIEF DESCRIPTION OF THE DRAWINGS

FIGS. 1(a) and 1(b) are structural cutaway views of electromagnetic shielding adhesive tapes using a metal foil as a backing in the prior art;

FIGS. 2(a) and 2(b) are typical structural cutaway views of electromagnetic shielding adhesive tapes using a resin thin film coating with a metal layer as a backing in the prior art;

FIG. 3 is a structural cutaway view of an electromagnetic shielding adhesive tape according to an embodiment of the invention.

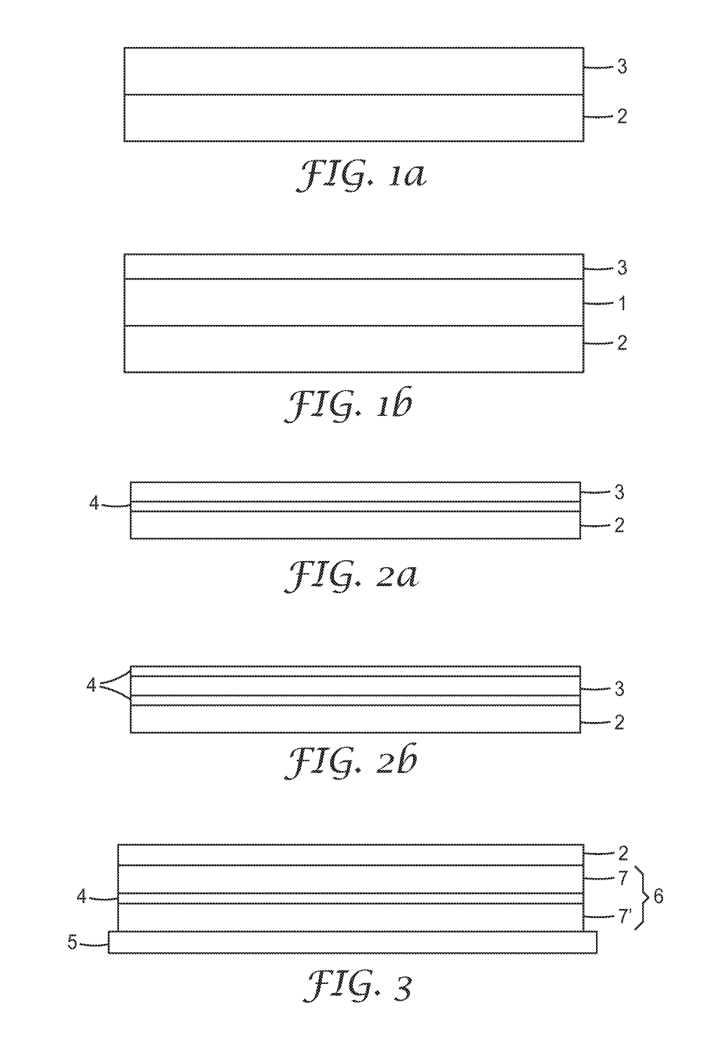

### DETAILED DESCRIPTION

In the invention, unless specifically stated, the term “high temperature” means a temperature of 70° C. or more, and specifically, a temperature of 85° C. or more. The term “high humidity” means a humidity of 85% RH (relative humidity) or more.

Unless specifically stated, the term “acrylate” has a scope covering acrylate, methacrylate and the mixtures thereof.

The invention provides an electromagnetic shielding adhesive tape, comprising:
a resin film layer; and
an electro-magnetic interference shielding layer with a sandwiched structure, which is laminated with the resin film layer and comprises:
   a first adhesive layer bonded to one side of the resin film layer;
   a second adhesive layer; and
   a conductive metal layer provided between the first adhesive layer and the second adhesive layer.

In the invention, the kind of the resin thin film is not specifically limited, for example, it can be a thin film made of polyethylene terephthalate (PET), polyethylene (PE), polypropylene (PP), polyurethane (PU), polyimide (PI), nylon, or various mixtures of the above resins. According to some preferable embodiments, the resins applicable to the invention are preferably those having transparency, insulation and high tearing resistant strength, such as, PET, PU or the like. The thickness and number of the resin thin film layer are not specifically limited. In the invention, only one resin thin film layer can be utilized, and additionally, two or more of the resin thin film layers can further be utilized. These resin thin film layers can be made of the same or different resin materials. According to some preferable embodiments, the resin thin film layer has a thickness of 5-100 μm, preferably, 10-75 μm, and more preferably, 10-50 μm.

In the electromagnetic shielding layer with a sandwich laminated structure, the first adhesive layer and the second adhesive layer are non-conductive and can made of the same or different adhesives. Additionally, the thicknesses thereof can also be the same or different. Such as, the thicknesses can independently be 5-200 μm, preferably, 10-80 μm. The kind of the adhesive used in the first adhesive layer can be selected according to the surface property of the resin thin film layer to which first adhesive layer is to bond and the desired adhesive force. The kind of the adhesive used in the second adhesive layer can be selected according to the property of the surface to which the second adhesive layer is to bind and the desired adhesive force.

The adhesive applicable to the invention is not specifically limited, and the examples thereof include, but not limited to, pressure sensitive adhesives, thermosols, and thermosetting adhesives.

According to some preferable embodiments, the first adhesive layer and the second adhesive layer are made of the same or different pressure sensitive adhesives (such as, acrylate type pressure sensitive adhesives). Pressure sensitive adhesive (PSA) is a pressure sensitive adhesive which can cause firm adhesion with an adherent in the case of applying light finger pressure without the help of solvents, heat or other means. A characteristic of pressure sensitive adhesives is that the adhesive layer thereof will not dry for a relatively long time. Therefore, the pressure sensitive adhesives are commonly referred to as “non-drying adhesive”.

The pressure sensitive adhesives applicable to the invention include, but not limited to:

(1) rubber type pressure sensitive adhesives, mainly comprising natural rubber pressure sensitive adhesives, synthetic and regenerated rubber pressure sensitive adhesives, and thermoplastic elastomer pressure sensitive adhesives. The rubber type pressure sensitive adhesives are a kind of pressure sensitive adhesives which has been applied most early, which has the features of cheap price and wide application. However, the largest problem thereof is the inferior aging resistant performance, and therefore, it is not preferable in the invention. The rubber type pressure sensitive adhesives are commercially available. For example, they can be obtained under a trade name of LMR-1011 from Dongguan Sanyi Adhesive Article Co. Ltd. (Dongguan, Guangdong), or under a trade name of MG-30 from Jinjiang Henghe adhesive Industrial Co. Ltd. (Jinjiang, Jiangsu).

(2) silicone resin type pressure sensitive adhesives, which have extremely excellent high temperature resistant and aging resistant performances and therefore are particularly preferable for the invention. The silicone resin type pressure sensitive adhesives are commercially available. For example, they can be obtained under the trade names of Dow Corning® 280A, 282, 7355, 7358Q2-7566 from Dow Corning Corporation, Corporate Center, PO Box 994, MIDLAND Mich. 48686-0994, United States.

(3) acrylate type pressure sensitive adhesives, which are obtained by copolymerizing various acrylate monomers and have superior weather resistance and performance-price ratio. Therefore, they are particularly preferable for the invention.

The acrylate type pressure sensitive adhesives are mainly formed by copolymerizing acrylate monomers, which have good transparency, coherence strength and binding performance, especially superior binding performance for a polar adherent surface and a porous surface, as well as extremely good aging resistant performance. The composition of an acrylate type pressure sensitive adhesive generally comprises the following parts of: an acrylate type pressure sensitive adhesive substrate (an acrylate raw adhesive), which constitutes the main body of the pressure sensitive adhesive and is a (meth)acrylate resin prepared by subjecting (meth)acrylate monomers with unsaturated double bonds to radical polymerization under the effect of a catalyst; an adhesion-promoting resin with a main function of providing the pressure sensitive adhesive with necessary adhesion, and the common adhesion-promoting resins are mainly rosin and rosin ester, terpene resin, C5 petroleum resin or the like; a cross-linking agent for improving the cohesive force of the pressure sensitive adhesive and increasing the weather resistance, hot resistance, oil resistance and solvent resistance or the like thereof, wherein various cross-linking agents depending on the different chemical compositions of the acrylate raw adhesive can be added. An organic solvent such as toluene, ethyl acetate or the like is mainly used to improve the formulation of the pressure sensitive adhesive, to adjust the solid content, to improve the flowability, to facilitate operation and coating.

The acrylate type pressure sensitive adhesives applicable to the invention are commercially available. For example, they can be obtained under a trade name of SM30 from Shimei Fine Chemical Co. Ltd. (Kunshan, Jiangsu), or under the trade names of M029, M017, M029 from Changxing Chemical (Kunshan, Jiangsu).

The pressure sensitive adhesive applicable to the invention has an adhesion force of 0.2 N/mm or more. The adhesion is measured by the 180° peeling force testing method defined in ASTM D3330. The selected testing plates are stainless steel plates according to ASTM standard. The pressure sensitive adhesive has a dry adhesive thickness of 0.05 mm. A PET film with a thickness of 0.05 mm is used as the backing The residence times of the samples on the steel plates at room temperature are 20 minutes respectively.

In addition to the first adhesive layer and the second adhesive layer, the electromagnetic shielding layer with a sandwich laminated structure further comprises a conductive metal layer located between the first adhesive layer and the second adhesive layer. In some preferable embodiments, the metal layer is formed by directly preparing a metal layer on a surface of one of the first adhesive layer and the second adhesive layer (preferably, the first adhesive layer) in manner of magnetic controlling sputtering plating (sputtering plating) process or evaporation plating film (evaporation plating) process. Then, the electromagnetic shielding layer with a sandwich laminated structure can be obtained by providing another adhesive layer on the conductive metal layer. The kinds of the conductive metals include, but not limited to, gold, platinum, silver, palladium, copper, titanium, nickel, aluminum, iron, chromium, and alloys formed by two or more of the above metals, such as stainless steel. Wherein, it is preferable to select copper, aluminum, nickel, chromium, titanium (which have relatively good oxidation resistance but poor conductive performance), more preferable to select silver or silver-palladium alloy (which have better conductivity and oxidation resistance), and most preferable to select gold, platinum, or palladium (which have the best conductivity and oxidation resistance, however, the prices thereof are expensive). The conductive plating layer can be a single plating layer prepared by using the above metals or alloys, and can also be a multiple plating layer prepared by using the above metals or alloys, such as the multi-layer plating layer with a sandwich structure formed by nickel/silver/nickel.

The process for metal plating is known and mainly includes evaporation plating film (evaporation plating) process and magnetic controlling sputtering plating (sputtering plating) process. As to the evaporation plating film (evaporation plating) process, the apparatus used in the process is generally composed of a vacuum cavity, a vacuum exhauster set, a winding system, a heating evaporation system, an electric controlling system and other assistant systems. The process is characterized in that: under a vacuum condition, in manner of resistance heating or induction heating, a metal or alloy material is heated to form a vapor of the corresponding metal or alloy; then, the vapor re-coagulates into a solid phase on a surface of the substrate to be plated, and thus, a metal plating layer is formed on the plating surface of the substrate. Wherein, a degree of vacuum for forming a film layer with relatively high quality is generally between 1×10⁻² Pa and 1 Pa. As to the magnetic controlling sputtering plating (sputtering plating) process, the process apparatus thereof is generally composed of a vacuum cavity, a vacuum exhauster set, a winding system, a magnetic controlling sputtering cathode, an electric controlling system and other assistant systems. Additionally, the magnetic controlling sputtering cathode is well insulated from the vacuum cavity and the winding system. The vacuum cavity and the winding system are well earthed. The process is characterized in that: utilizing a single or several magnetic controlling sputtering cathodes and loading the cathodes with a target material prepared by the above metals or alloys, such as gold, silver, titanium, nickel-chromium alloy or the like; then, loading a substrate to be plated (herein, the substrate refers to a film material which has been coated with an adhesive) on the winding system; vacuumizing the apparatus; introducing therein an inert gas (such as argon, helium or neon); subjecting the target to negative bias pressure, while starting the winding system to move the substrate. At this time, the discharge between the target and the substrate forms stable plasmas. Therefore, the metal atoms and atomic groups on the target will deposit on a surface of the film material to form a metal plating layer. Wherein, the degree of vacuum upon the magnetic controlling sputtering plating is generally between 1×10⁻¹ Pa and 1 Pa.

The thickness of the conductive metal layer is not particular limited in the invention, for example, it can be 1 nm-1000 nm, preferably, 10 nm-800 nm, and more preferably, 20 nm-400 nm.

According to some embodiments, the electromagnetic shielding adhesive tape of the invention further comprises a release paper (film) which is provided on an outside surface of the second adhesive layer of the electromagnetic shielding adhesive tape (that is, on the surface opposite to the conductive metal layer). The release paper can be a kraft paper, a Glassine paper, or a plastic rinsing kraft paper coated with a silicone oil layer. The release film can be a polyethylene terephthalate (PET) or polyethylene (PE) film coated with a silicone oil layer.

The adhesive tape structure related in the invention is specified in detail below in combination with FIG. 3. FIG. 3 provides a cutaway view of an electromagnetic shielding adhesive tape according to an embodiment of the invention. In FIG. 3, the electromagnetic shielding adhesive tape comprises a trilaminated structure, that is, a release paper (film) 5, a resin thin film 3 and an electromagnetic shielding layer 6 with a sandwich laminated structure. The electromagnetic shielding layer 6 comprises a first adhesive layer 7 and a second adhesive layer 7′ made of a pressure sensitive adhesive, and a conductive metal layer 4 located between the first adhesive layer 7 and the second adhesive layer 7′.

The electromagnetic shielding adhesive tape with a novel structure according to the invention can greatly eliminate and solve the disadvantages of the traditional metal foil type electromagnetic shielding adhesive tapes: for example, the metal (specifically, copper) is oxidized easily; the whole adhesive tape is poorer in softness and compliance performances, the tape tends to produce folds; producing fins, crimping upon die-cutting easily; the adhesive tape has a thicker thickness, or the like. Additionally, the electromagnetic shielding adhesive tape of the invention has better softness, compliance, and die-cutting performance. Because no metal foil is used as a backing anymore, the production and preparation of an ultra-thin electromagnetic shielding adhesive tape is more convenient and feasible. This can satisfy the designing demand of “lightness, thin and durability” for the present consumptive electronic products. For example, because the thickness of the conductive metal layer is neglectable as compare with that of the material of other respective layers, when the thickness of the resin thin film is 13-20 μm and the total thickness of the two pressure sensitive conductive adhesive film is 20-40 μm, the total thickness of the adhesive tape can be 33-60 μm. At the same time, because of the presence of the resin thin film, this adhesive tape can further provide some protection function of insulation. Simultaneously, because the invention utilizes a special sandwich structure, the reduction of electromagnetic shielding performance caused by the oxidation of the traditional copper foil or the like can be reduced and prevented. The novel electromagnetic shielding adhesive tape of the invention can be widely used to provide electromagnetic shielding and protection for the key parts in electronic products, and specifically, consumptive electronic products.

In the invention, unless specifically stated, all of contents, proportions and parts are based on weight, and all temperatures are based on centigrade.

### EXAMPLES

The raw materials and sources used in the following examples are as follows:

acrylate pressure sensitive raw adhesive: SM30, Shimei Fine Chemical Co. Ltd. (Kunshan, Jiangsu)

cross-linking agent: RD1054, 3M, Minnesota, US

ethyl acetate: Sinopharm Chemical Reagent Co., Ltd. Shanghai

adhesion-promoting resin: RE80HP, Arizona Chemical, Florida, US

Performance Testing:

The main performances of an electromagnetic shielding adhesive tape are adhesion and electromagnetic shielding efficiency (SE).

Adhesion Testing:

The adhesion is measured by the 180° peeling force testing method defined in ASTM D3330. The selected testing plates are stainless steel plates according to ASTM standard. The residence times of the samples on the steel plates at room temperature are 20 minutes and 72 hours, respectively. In order to test the aging resistant performance of the materials, two aging conditions of high temperature (70° C./72 hours) and high temperature high humidity (85 ° C./85% RH/72 hours) are selected simultaneously.

Electromagnetic Shielding Efficiency Testing:

The electromagnetic shielding efficiency (SE) is measured by the method according to ASTM D4935. The scanning frequency is 1 GHZ˜3 GHZ. In order to test the aging resistant performance of the materials, two aging conditions of high temperature (70° C./72 hours) and high temperature high humidity (85 ° C./85% RH/72 hours) are also selected.

### Example 1

Preparation of Tape:

An acrylate raw adhesive was mixed uniformly with ethyl acetate, an adhesion-promoting resin and a cross-linking agent, and then coated on a plastic rinsing kraft paper coated with a silicone oil layer. After drying, a pressure sensitive adhesive tap with a thickness of 1.2 mils (30 μm) was prepared. A portion of the above adhesive tape was cut and a surface (the surface of non-release paper) of the adhesive tape was deposited with a layer of conductive metal utilizing the magnetic controlling sputtering plating (sputtering plating) process. The metal sputtering sequence was nickel, silver, nickel. The thicknesses of respective layers were 30 nm, 80 nm, 25 nm, respectively. The total thickness of the sputtering metals was 135 nm. Additionally, a portion of the above adhesive tape was cut and the surface of non-release paper was attached to a 1.5 mils (38 μm) PET film, and simultaneously, the original release paper was peeled off. Subsequently, the adhesive side obtained by peeling the release paper off was attached to the above metal surface to obtain a desired electromagnetic shielding adhesive tape. The total thickness of the obtained adhesive tape was 96 μm.

Performance Testing:

The adhesion and electromagnetic shielding efficiency (SE) of the electromagnetic shielding adhesive tape were tested according to the methods described above. The testing results of adhesion were shown below in Table 1:

TABLE 1
Adhesion testing results of the adhesive tape in example 1

| 20 minutes | 72 hours | 70° C./72 hours | 85° C./85% RH |
|---|---|---|---|
| (N/mm) | (N/mm) | (N/mm) | 72 hours (N/mm) |
| 0.70 | 0.74 | 0.95 | 1.14 |

The testing results of electromagnetic shielding efficiency (SE) showed that: there was no obvious difference between the results from the adhesive tapes under the two aging conditions and the results from the original adhesive tape. All of them are 45-50 dB. Additionally, there is no change in the appearance of the adhesive tapes.

### Example 2

Preparation of Tape:

An acrylate raw adhesive was mixed uniformly with ethyl acetate, an adhesion-promoting resin and a cross-linking agent, and then coated on a plastic rinsing kraft paper coated with a silicone oil layer. After drying, a pressure sensitive adhesive tap with a thickness of 0.5 mils (13 μm) was prepared. A portion of the above adhesive tape was cut and a surface (the surface of non-release paper) of the adhesive tape was deposited with a layer of conductive metal utilizing the magnetic controlling sputtering plating (sputtering plating) process. The metal sputtering sequence was nickel, copper, nickel. The thicknesses of respective layers were 40 nm, 100 nm, 50 nm, respectively. The total thickness of the sputtering metals was 190 nm. Additionally, a portion of the above adhesive tape was cut and the surface of non-release paper was attached to a 0.5 mils (13 μm) PET film, and simultaneously, the original release paper was peeled off. Subsequently, the adhesive side obtained by peeling the release paper off was attached to the above metal surface to obtain a desired electromagnetic shielding adhesive tape. The total thickness of the obtained adhesive tape was 40 μm.

Performance Testing:

The adhesion and electromagnetic shielding efficiency (SE) of the electromagnetic shielding adhesive tape were tested according to the methods described above. The testing results of adhesion were shown below in Table 2:

TABLE 2
Adhesion testing results of the adhesive tape in example 2

| 20 minutes | 72 hours | 70° C./72 hours | 85° C./85% RH |
|---|---|---|---|
| (N/mm) | (N/mm) | (N/mm) | 72 hours (N/mm) |
| 0.40 | 0.46 | 0.58 | 0.66 |

The testing results of electromagnetic shielding efficiency (SE) showed that: there was no obvious difference between the results from the adhesive tapes under the two aging conditions and the results from the original adhesive tape. All of them are 45-50 dB. Additionally, there is no change in the appearance of the adhesive tapes.

### Example 3

Preparation of Tape:

An acrylate raw adhesive was mixed uniformly with ethyl acetate, an adhesion-promoting resin and a cross-linking agent, and then coated on a plastic rinsing kraft paper coated with a silicone oil layer. After drying, a pressure sensitive adhesive tap with a thickness of 2.0 mils (50 μm) was prepared. A portion of the above adhesive tape was cut and a surface (the surface of non-release paper) of the adhesive tape was deposited with a layer of conductive metal nickel utilizing the magnetic controlling sputtering plating (sputtering plating) process. The thickness of nickel layer was 20 nm. Additionally, a portion of the above adhesive tape was cut and the surface of non-release paper was attached to a 1.0 mils (25 μm) PET film, and simultaneously, the original release paper was peeled off. Subsequently, the adhesive side obtained by peeling the release paper off was attached to the above metal surface to obtain a desired electromagnetic shielding adhesive tape. The total thickness of the obtained adhesive tape was 125 μm.

Performance Testing:

The adhesion and electromagnetic shielding efficiency (SE) of the electromagnetic shielding adhesive tape were tested according to the methods described above. The testing results of adhesion were shown below in Table 3:

TABLE 3
Adhesion testing results of the adhesive tape in example 3

| | | | 85° C./ |
|---|---|---|---|
| | | 70° C./ | 85% RH |
| 20 minutes | 72 hours | 72 hours | 72 hours |
| (N/mm) | (N/mm) | (N/mm) | (N/mm) |
| 0.87 | 0.95 | 1.11 | 1.29 |

The testing results of electromagnetic shielding efficiency (SE) showed that: there was no obvious difference between the results from the adhesive tapes under the two aging conditions and the results from the original adhesive tape. All of them are 20-25 dB. Additionally, there is no change in the appearance of the adhesive tapes.

### Example 4

Preparation of Tape:

An acrylate raw adhesive was mixed uniformly with ethyl acetate, an adhesion-promoting resin and a cross-linking agent, and then coated on a plastic rinsing kraft paper coated with a silicone oil layer. After drying, a pressure sensitive adhesive tap with a thickness of 1 mils (25 μm) was prepared. A portion of the above adhesive tape was cut and a surface (the surface of non-release paper) of the adhesive tape was deposited with a layer of conductive metal silver utilizing the evaporation plating film (evaporation plating) process. The thickness of silver layer was 100 nm. Additionally, a portion of the above adhesive tape was cut and the surface of non-release paper was attached to a 1.0 mils (25 μm) PET film, and simultaneously, the original release paper was peeled off. Subsequently, the adhesive side obtained by peeling the release paper off was attached to the above metal surface to obtain a desired electromagnetic shielding adhesive tape. The total thickness of the obtained adhesive tape was 74 μm.

Performance Testing:

The adhesion and electromagnetic shielding efficiency (SE) of the electromagnetic shielding adhesive tape were tested according to the methods described above. The testing results of adhesion were shown below in Table 4:

TABLE 4
Adhesion testing results of the adhesive tape in example 4

| | | 70° C./ | 85° C./ |
|---|---|---|---|
| 20 minutes | 72 hours | 72 hours | 85% RH |
| (N/mm) | (N/mm) | (N/mm) | 72 hours (N/mm) |
| 0.62 | 0.65 | 0.82 | 0.97 |

The testing results of electromagnetic shielding efficiency (SE) showed that: there was no obvious difference between the results from the adhesive tapes under the two aging conditions and the results from the original adhesive tape. All of them are 35-40 dB. Additionally, there is no change in the appearance of the adhesive tapes.

What is claimed is:

1. An electro-magnetic interference shielding tape, comprising:
a resin film layer; and
an electro-magnetic interference shielding layer with a sandwiched structure, which is laminated with the resin film layer and comprises:
a first adhesive layer bonded to one side of the resin film layer;
a second adhesive layer; and
a conductive metal layer provided between the first adhesive layer and the second adhesive layer.

2. The electro-magnetic interference shielding tape according to claim 1, further comprising a release paper or a release film provided on the opposite side of the second adhesive layer to the conductive metal layer.

3. The electro-magnetic interference shielding tape according to claim 1,wherein the resin film layer is made of a material selected from the group consisting of polyethylene terephthalate, polyethylene, polypropylene, polyurethane, polyimides, nylons, or mixtures thereof.

4. The electro-magnetic interference shielding tape according to claim 1, wherein the first adhesive layer is a pressure sensitive adhesive layer.

5. The electro-magnetic interference shielding tape according to claim 1, wherein the second adhesive layer is a pressure sensitive adhesive layer.

6. The electro-magnetic interference shielding tape according to claim 4 or 5, wherein the first adhesive, the second adhesive or both, is a silicone adhesive, an acrylate adhesive, a natural or synthetic rubber adhesive, or a combination thereof.

7. The electro-magnetic interference shielding tape according to claim 1, wherein the conductive metal layer is a metal layer formed by a magnetron sputtering process or a vacuum vapor deposition process.

8. The electro-magnetic interference shielding tape according to claim 1, wherein the conductive metal is at least one selected from the group consisting of Au, Pt, Ag, Pd, Cu, Ti, Ni, Al, Fe, Cr or alloys thereof.

9. The electro-magnetic interference shielding tape according to claim 1, wherein the conductive metal is a stainless steel.

10. The electro-magnetic interference shielding tape according to claim 1, wherein the conductive metal layer is a multi-layered structure formed by a plurality of conductive metal sub-layers.

11. The electro-magnetic interference shielding tape according to claim 10, wherein the conductive metal layer is a multi-layered structure of Ni/Ag/Ni or Ni/Cu/Ni.

12. The electro-magnetic interference shielding tape according to claim 1, wherein the conductive metal layer has a thickness of 1-1000 nm.

13. The electro-magnetic interference shielding tape according to claim 1, wherein the first adhesive layer has a thickness of 5-200 micrometers.

14. The electro-magnetic interference shielding tape according to claim 1, wherein the second adhesive layer has a thickness of 5-200 micrometers.

15. The electro-magnetic interference shielding tape according to claim 1, wherein the resin film layer has a thickness of 5-100 micrometers.
